(19) United States
(12) Patent Application Publication
(10) Pub. No.: US 2011/0284956 A1
(43) Pub. Date: Nov. 24, 2011

(54) SEMICONDUCTOR DEVICE AND PRODUCTION METHOD THEREOF

(76) Inventors: Yoshinobu SATOU, Osaka (JP); Satoshi Suzuki, Kyoto (JP)

(21) Appl. No.: 13/101,675

(22) Filed: May 5, 2011

(30) Foreign Application Priority Data
May 21, 2010 (JP) 2010-117326

(51) Int. Cl. H01L 29/78; H01L 21/336

(52) U.S. Cl. 257/335; 438/286; 257/E29.256; 257/E21.417

(57) ABSTRACT

The semiconductor device comprises a first impurity region having a second conductivity type and formed in a semiconductor layer having a first conductivity type; a body region adjacent to and in contact with the first impurity region and having the first conductivity type; a second impurity region formed in the first impurity region, having the second conductivity type, and having a depth smaller than the first impurity region; a source region formed in the body region and having the second conductivity type; a drain region formed in the second impurity region and having the second conductivity type; and a gate electrode formed via a gate insulating film. In a preferable mode of the semiconductor device, the second impurity region has a higher impurity concentration than the first impurity region and the first impurity region has a depth of 1 μm or smaller.

### CROSS REFERENCE TO RERATED APPLICATION

The disclosure of Japanese Patent Application No.2010-117326 filed May 21, 2010 including specification, drawings and claims is incorporated herein by reference in its entirety.

### BACKGROUND OF THE INVENTION

1. Field of the Invention

The present invention relates to a structure and production method of semiconductor devices, particularly high voltage MOS type semiconductor devices.

2. Description of the Related Art

High voltage MOS type semiconductor devices, particularly LDMOS (lateral double diffused MOS) type semiconductor devices are utilized in most product fields such as wireless base station circuits, information home appliance, vehicle semiconductor integrated circuits, LED driver ICs, and motor driver ICs. They have a wide range of operation voltages from a ten plus several V to several tens V. For example, in regard to various driver ICs among semiconductor products, progress has been made particularly in lower power consumption and reduced chip sizes while there is a demand for higher voltage resistance and lower on-resistance.

DMOS type semiconductor devices including the LDMOS type utilize the difference in diffusibility of impurities of different conductivity types for forming a channel in the course of forming a source region and a body region. Then, a short channel can easily be obtained, which characteristically leads to lower on-resistance. Continuous efforts have been made on technology development for higher voltage resistance and lower on-resistance in DMOS type semiconductor devices.

However, it is inevitable that high voltage resistance and low on-resistance have a trade-off relationship in DMOS type semiconductor devices as in other conventional high voltage-resistant devices. One of the major components affecting this trade-off relationship is the drain offset region. In order to achieve high voltage resistance, for example, a key point is how to create a low impurity concentration drain offset region for extending a depletion layer. On the other hand, in order to achieve low on-resistance, a key point is how to create a high impurity concentration drain offset region for diminishing the resistance factor.

Japanese Unexamined Patent Application Publication No. 2000-164860 (Prior Art Document 1) has proposed a technique for achieving the above higher voltage resistance and lower on-resistance in LDMOS transistors. FIG. 11 is a cross-sectional view of an N channel type LDMOS transistor described in the Prior Art Document 1. In FIG. 11, a P type well region 21 is formed on a P type semiconductor substrate 1 and an N-layer 22 and a P type body region 3 are formed in the region 21. An N type diffused region 4 serving as a source region is formed in the body region 3 and an N type diffused region 5 serving as a drain region is formed in the N-layer 22. In such a structure, particularly, the N-layer 22 is shallow below the gate electrode 7 (the first N-layer 22A) and deep near the drain region 5 (he second N-layer 22B).

The above N-layer 22 is formed by double ion implantation of arsenic and phosphorus. The first N-layer 22A in the surface part of the substrate has a higher impurity concentration and the second N-layer 22B has a lower impurity concentration. In this way, the first N-layer 22A having a higher impurity concentration below the gate electrode 7 has a lower on-resistance, allowing a current to flow easier. On the other hand, the second N-layer 22B having a lower impurity concentration near the drain region 5 allows a depletion layer to extend easier for high voltage resistance.

Japanese Unexamined Patent Application Publication No. 9-260651 (Prior Art Document 2) also describes a technique for increasing the voltage resistance and lowering the on-resistance in a DMOS type semiconductor device for improved trade-off relationship.

### SUMMARY OF THE INVENTION

The structure of a prior art high voltage MOS type semiconductor device as disclosed in the Prior Art Document 1 at least achieves high voltage resistance and low on-resistance; however, it has the following problems. As described above, the N-layer 22 of a LDMOS transistor shown in FIG. 11 has an impurity concentration profile that is particularly high in the first N-layer 22A and the surface part of the second N-layer 22B and low in the lower part of the second N-layer 22B. Therefore, the impurity concentration of the N-layer 22 is presumably high near the interface with the LOCOS oxide film 9. When a high voltage is applied between the source region (N type diffused region 4) and drain region (N type diffused region 5) of this transistor, the PN junctions between the N-layer 22 and P type body region 3 and between the N-layer 22 and P type well region 21 are inversely-biased; then, a depletion layer extends in the N-layer 22.

However, the depletion does not advance near the interface with the LOCOS oxide film 9 where the impurity concentration is high. The equipotential line is significantly tilted toward the interface with the LOCOS oxide film 9 from the vertical direction and a high electric field oriented toward the LOCOS oxide film 9 occurs. Particularly, the electric field tends to be high around the bird's peak of the LOCOS oxide film 9 below the gate electrode 7. In this high electric field domain of the N-layer 22, electrons accelerated by the electric field and highly energized are injected around the interface between the LOCOS oxide film 9 and N-layer 22 so as to become fixed charge. The fixed charge gradually changes the electric field profile in the N-layer 22 near the interface with the LOCOS oxide film 9.

As the cumulative time that the transistor operates under a high voltage as described above is increased, various characteristics including voltage resistance may change over time or there may be a higher risk of increased junction leak. In some actual usage of the transistor, it is difficult to maintain stable characteristics, lowering the reliability.

In view of the above problems, the purpose of the present invention is to provide a semiconductor device and production method thereof restraining various electrical characteristics from changing over time in the course of operation for preventing deterioration in reliability and capable of achieving both high voltage resistance and low on-resistance. The present invention is intended to resolve at least one of the above problems.

A semiconductor device according to the present invention in order to resolve the above problems comprises a semiconductor layer having a first conductivity type; a first impurity region formed in the surface part of the semiconductor layer and having a second conductivity type; a body region adjacent to and in contact with the first impurity region and having the first conductivity type; a second impurity region formed in the first impurity region with a distance from the body region, having the second conductivity type, and having a depth smaller than the first impurity region; a source region formed in the surface part of the body region and having the second conductivity type; a drain region formed in the surface part of the second impurity region and having the second conductivity type; and a gate electrode formed from above the end of the source region that is closer to the drain region to a region above the first impurity region via a gate insulating film.

It is possible in the above semiconductor device that the body region has a larger depth than the first impurity region and the maximum curvature portion of the border of the body region is at a lower level than the bottom of the first impurity region.

In a particularly desirable mode of the above semiconductor device, the first impurity region has a depth of 1 μm or smaller so as to suppress change in electric characteristics of the semiconductor device over time in the course of operation.

Furthermore, it is desirable that the second impurity region has a higher impurity concentration than the first impurity region so that the semiconductor device has a low on-resistance. For ensuring that change in electric characteristics of the semiconductor device is suppressed, the second impurity region is formed within 1 μm from the end of the drain region that is closer to the source region in the direction to the source region on the surface.

It is also possible in the above semiconductor device according to the present invention that an embedded layer having the first conductivity type and a higher impurity concentration than the semiconductor layer is formed below the semiconductor layer. Furthermore, it is possible that of the maximum curvature portions of the border of the second impurity region, the portion closer to the source region is included in the first impurity region and a part of the second impurity region is horizontally exposed outside of the first impurity region.

Another semiconductor device according to the present invention in order to resolve the above problems has a first semiconductor device comprising a semiconductor layer having a first conductivity type; a first impurity region formed in the surface part of the semiconductor layer and having a second conductivity type; a first body region adjacent to and in contact with the first impurity region and having the first conductivity type; a second impurity region formed in the first impurity region with a distance from the first body region, having the second conductivity type, and having a depth smaller than the first impurity region; a first source region formed in the surface part of the first body region and having the second conductivity type; a first drain region formed in the surface part of the second impurity region and having the second conductivity type; and a gate electrode formed from above the end of the first source region that is closer to the first drain region to a region above the first impurity region via a gate insulating film, and a second semiconductor device comprising the semiconductor layer; a second body region formed in the surface part of the semiconductor layer, having the same depth and impurity concentration as the second impurity region, and having the second conductivity type; a third impurity region formed in the surface part of the semiconductor layer with a distance from the second body region and having the first conductivity type; a second source region formed in the surface part of the second body region and having the first conductivity type; a second drain region formed in the surface part of the third impurity region and having the first conductivity type; and a gate electrode formed from above the end of the second source region that is closer to the second drain region to a region above the semiconductor layer via a gate insulating film.

In this semiconductor device, the second impurity region and the second body region can be formed concurrently in the same production step.

The semiconductor device production method according to the present invention in order to resolve the above problems includes the following steps: forming a first impurity region having a second conductivity type in the surface part of a semiconductor layer having a first conductivity type; forming a gate insulating film on the surface of the first impurity region; forming a gate electrode on the gate insulating film; introducing an impurity having the first conductivity type in the first impurity region using the gate electrode as a mask to form a body region; introducing an impurity having the second conductivity type in the first impurity region at a given position away from the body region to form a second impurity region having a depth smaller than the first impurity region; introducing an impurity having the second conductivity type in the body region using the gate electrode as a mask to form a source region; and introducing an impurity having the second conductivity type in the second impurity region to form a drain region.

The above production method may further includes a step of introducing an impurity having the first conductivity type in the semiconductor substrate to form an embedded layer having a higher impurity concentration than the semiconductor layer and a step of forming the semiconductor layer on the embedded layer.

It is desirable that the semiconductor device according to the present invention is so produced as to have the first impurity region having a depth of 1 μm or smaller.

The semiconductor device according to the present invention comprises, as described above, a first impurity region and a second impurity region formed in the first impurity region and having a smaller depth than the first impurity region. Particularly, when the first impurity region has a depth of 1 μm or smaller, an extremely large, local electric field in the surface part is prevented; then, the electric field intensity is alleviated and the voltage resistance is improved. With these effects, change in electric characteristics of the semiconductor device over time in the course of operation can be suppressed.

Furthermore, when the second impurity region has a smaller depth than the first impurity region and a higher impurity concentration than the first impurity region, highest electric field occurs inside the first impurity region away from the surface. In this way, change in electric characteristics of the semiconductor device over time in the course of operation can also be suppressed. Furthermore, a high impurity concentration of the second impurity region contributes to realizing a low on-resistance in the semiconductor device.

Structures according to the present invention other than the above also provide various beneficial effects, which will be apparent from embodiments described below.

### BRIEF DESCRIPTION OF THE DRAWINGS

FIG. 1 is a cross-sectional view of a semiconductor device according to Embodiment 1 of the present invention;

FIG. 2 is an illustration showing the planar layout of the semiconductor device according to Embodiment 1 of the present invention;

FIG. 3 is a graphical representation showing impurity concentration profiles in the drain offset region of the semiconductor device according to the present invention;

FIG. 4 is an illustration of cross-sectional views depicting the process of the method of producing the semiconductor device according to Embodiment 1 of the present invention as Embodiment 2 of the present invention;

FIG. 5 is an illustration of cross-sectional views depicting the process of the method of producing the semiconductor device according to Embodiment 1 of the present invention as Embodiment 2 of the present invention;

FIG. 6 is an illustration of cross-sectional views depicting the process of the method of producing the semiconductor device according to Embodiment 1 of the present invention as Embodiment 2 of the present invention;

FIG. 7 is a cross-sectional view of a semiconductor device according to Embodiment 3 of the present invention;

FIG. 8 is a cross-sectional view of a semiconductor device according to Embodiment 4 of the present invention;

FIG. 9 is an illustration showing the planar layout of the semiconductor device according to Embodiment 4 of the present invention;

FIG. 10 is a cross-sectional view of a semiconductor device according to Embodiment 5 of the present invention; and

FIG. 11 is a cross-sectional view of a prior art LDMOS transistor.

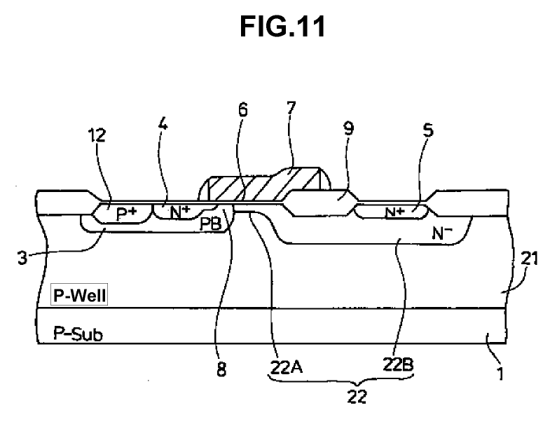

### DETAILED DESCRIPTION OF PREFERRED EMBODIMENTS

Embodiments according to the present invention will be described in detail hereafter with reference to the drawings. Here, the embodiments will be described on the basis of a P channel type high voltage semiconductor device as a specific example. Materials and numeric values in the embodiments are given by way of example and the present invention is not confined thereto. The embodiments may be modified as appropriate without departing from the technical scope of the present invention. Furthermore, the embodiments may be realized in combination.

### Embodiment 1

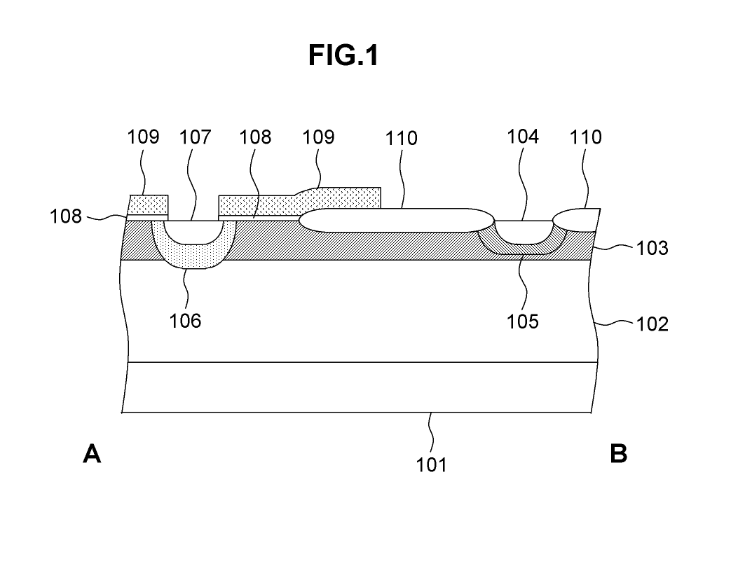

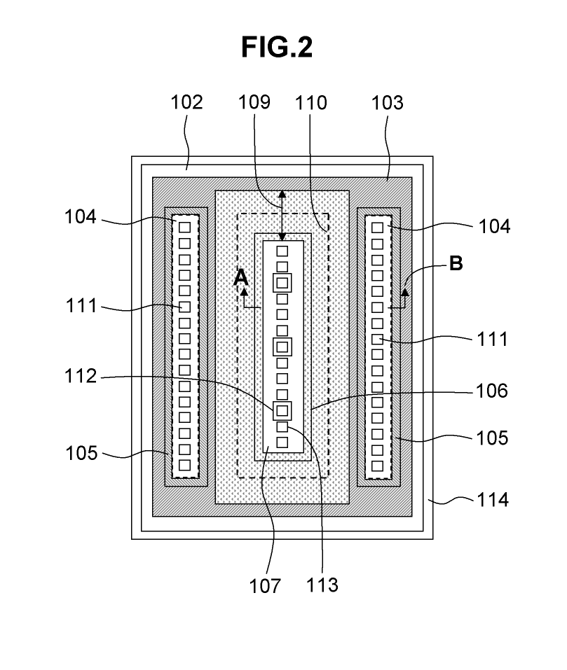

FIG. 1 is a cross-sectional view of a semiconductor device according to Embodiment 1 of the present invention, particularly a P channel LDMOS transistor driven by a high voltage. FIG. 2 is a planar layout showing the planar pattern thereof. FIG. 1 is shows a cross-section at the line A-B in FIG. 2. FIGS. 1 and 2 may show a discrete transistor or a part of a semiconductor integrated circuit having other semiconductor elements such as low voltage-driven MOS transistors.

The cross-sectional structure will be described with reference to FIG. 1. An N type semiconductor layer 102 having a thickness of 4 μm to 6 μm and an average impurity concentration of 1.0×10¹⁵ cm⁻³ to 5×10¹⁵ cm⁻³ is formed on a P type silicon substrate (semiconductor substrate) 101. The semiconductor layer 102 can be formed by an N type impurity thermal-diffused into the silicon substrate 101 or epitaxially grown on the silicon substrate 101. The semiconductor layer 102 can be a part of the N type semiconductor substrate as just described. In the present invention, whether the layer consists of the semiconductor substrate itself or an epitaxial layer, the above layer is termed the semiconductor layer 102.

A first drain offset region 103 is provided in the surface part of the semiconductor layer 102 as a P type first impurity region. The first drain offset region 103 has a depth of, for example, 0.9 μm below the surface and a P type impurity peak concentration of 1.0×10¹⁶ cm⁻³ to 5×10¹⁷ cm⁻³. As described later, it is preferable that the first drain offset region 103 has a depth of 1 μm or smaller, particularly smaller than 1 μm, below the surface. An N type body region 106 is formed through the first drain offset region 103 at a given position. The N type body region 106 has a depth of, for example, 1.2 μm below the surface.

In FIG. 1, the body region 106 is formed through the first drain offset region 103. However, these regions are assumed to be adjacent to and in contact with each other via a PN junction. Therefore, instead of the formation shown in FIG. 1, the body region 106 can be formed in a region of the semiconductor layer 102 where the first drain offset region 103 is absent in the manner that these regions are in contact with each other. A source region 107 as a higher concentration P type impurity layer is formed inside the body region 106.

A second drain offset region 105 as a P type second impurity region is provided in the surface part of the first drain offset region 103 with a horizontal distance from the body region 106 and source region 107. The second drain offset region 105 has a smaller depth than the first drain offset region 103 and a higher P type impurity peak concentration than the first drain offset region 103. The P type impurity peak concentration constituting the second drain offset region 105 can be, for example, 5×10¹⁷ cm⁻³ to 1×10¹⁸ cm⁻³.

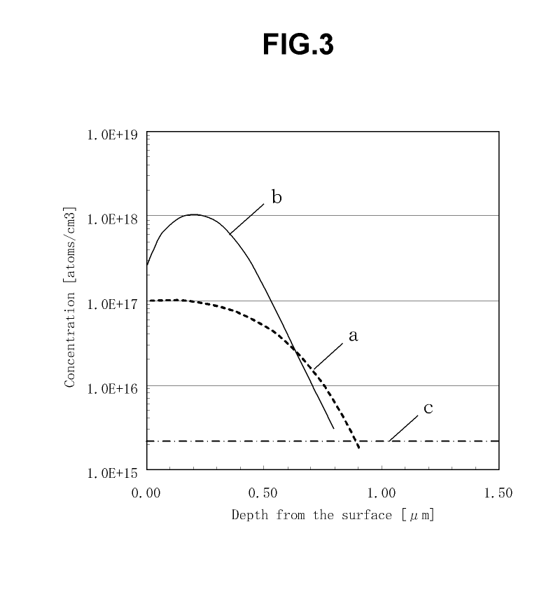

FIG. 3 is a graphical representation showing an example of impurity concentration profiles in the first and second drain offset regions 103 and 105 directly below the center part of the drain region 104 in the completed semiconductor device shown in FIG. 1. Here, the impurity concentration profile in the drain region 104 is not shown. In FIG. 3, the curve a presents the P type impurity concentration profile in the first drain offset region 103 and the curve b presents the P type impurity concentration profile in the second drain offset region 105. The nearly straight line c presents the N type impurity concentration profile in the semiconductor layer 102. In the example shown in FIG. 3, the semiconductor layer 102 has an impurity concentration of approximately 2×10¹⁵ cm⁻³. According to these lines, the first drain offset region 103 has a depth of 0.9 μm and the second drain offset region 105 has a depth of 0.65 μm.

As described above, the second drain offset region 105 is formed in the surface part of the first drain offset region 103 and has a smaller depth than the first drain offset region 103. Consequently, the first drain offset region 103 has a nearly flat bottom at least in the region of the semiconductor layer 102 where an LDMOS transistor is formed and a uniform depth below the surface. The drain region 104 is formed inside the second drain offset region 105 as a high concentration P type impurity layer.

A thick insulating film 110 consisting of an LOCOS oxide film is formed from the first drain offset region 103 located between the body region 106 and drain region 104 to the one end of the drain region 104 that is closer to the source region 107 or body region 106 via over the surface of the second drain offset region 105. The insulating film 110 also extends outward from the other end of the drain region 104. A gate insulating film 108 consisting of a silicon oxide film or the like is formed from above the end of the source region 107 and body region 106 to the end of the insulating film 110 via over the first drain offset region 103. A gate electrode 109 extends from on the gate insulating film 108 onto the thick insulating film 110.

The semiconductor device shown in FIG. 1 has a pattern layout as shown in FIG. 2 in a planar view. FIG. 2 shows the entire structure of the semiconductor device. A given region of the N type semiconductor layer 102 on the silicon substrate 101 (see FIG. 1) is partitioned by a rectangular, zonal element isolation region 114. The semiconductor device is formed in the region of the semiconductor layer 102 that is partitioned by the element isolation region 114. The element isolation region 114 generally consists of a PN junction isolation region. It can be a trench isolation formed by embedding an insulating material in a deep trench in the semiconductor layer 102. The first drain offset region 103 occupies a majority, rectangular area of the region. An elongated rectangular source region 107 is provided in the center part of the first drain offset region 103 and a body region 106 is provided around the source region 107.

An elongated drain region 104 and surrounding second drain offset region 105 are formed in a line-symmetric manner about the source region 107 or body region 106 with a given distance on either side of them. In the example of FIG. 2, the longitudinal direction of the drain region 104 is parallel to the longitudinal direction of the source region 107 and the former is larger in the longitudinal direction than the latter. However, the latter can be larger. The dotted line in FIG. 2 presents the borders of the insulating film 110 consisting of a LOCOS oxide film. The border of the opening of the insulating film 110 nearly coincides with the border of the drain region 104. The gate electrode 109 extends from the end of the source region 107 over the body region 106, the first drain offset region 103, and a part of the insulating film 110 so as to surround the source region 107 and body region 106.

Multiple rectangular contact holes 111, which are not shown in FIG. 1, are formed above the drain region 104 by opening an interlayer insulating film formed on the entire surface thereof. External electric connection is made via not-shown metal wiring provided on the contact holes 111. On the other hand, N type body contact regions 112 are formed at given positions within the source region 107. The P type impurity constituting the source region 107 is not introduced in the regions where the body contact regions 112 are formed; the N type body region 106 is directly exposed on the surface. An N type impurity is additionally introduced in these regions to a high concentration to form the body contact regions 112. Therefore, the body contact regions 112 are continued from the body region 106. Multiple rectangular contact holes 113 are formed on the source region 107 and body contact regions 112 also by opening the above-mentioned interlayer insulating film. External electric connection is made via a not-shown metal wire formed on the contact holes 113. Then, the source region 107 is short-circuited to the body contact regions 112 or body region 106.

The semiconductor device according to Embodiment 1 has the above structure.

Particularly the first drain offset region 103 of this semiconductor device has a smaller depth below the surface than prior art high voltage semiconductor devices such as LDMOS transistors. More precisely, it is smaller than 1 μm. In the semiconductor device according to the present invention, for example, when a ground potential is applied to the silicon substrate 101, semiconductor layer 102, source region 107, and gate electrode 109 and a negative high voltage is applied to the drain region 104, a depletion layer extends into the first drain offset region 103 from the first PN junction formed by the first drain offset region 103 and body region 106 and the second PN junction formed by the first offset region 103 and semiconductor layer 102. In all embodiments below, the voltage resistance or a breakdown voltage is referred to on the assumption that the semiconductor is biased as described above.

The first drain offset region 103 having a small depth contributes to effective upward extension of a depletion layer from the second PN junction; the entire first drain offset region 103 can be depleted. With the depth (smaller than 1 μm) and impurity concentration of the first drain offset region 103 being optimized, in such a state, a nearly uniform electric field distribution is obtained in the surface part of the first drain offset region 103 at least from the end of the second drain offset region 105 that is closer to the source region 107 to the end of the body region 106 that is closer to the drain region 104. Consequently, particularly the electric field near the first PN junction can be reduced. In this way, the breakdown voltage in the semiconductor device can be increased.

Furthermore, as described above, the electric field within the first drain offset region 103 can be smoothed and the equipotential line therein becomes approximately vertical; a potential gradient nearly constant in the crosswise direction is formed. Additionally, no particularly large electric field peak occurs in the surface part of the first drain offset region 103. These two effects substantially prevent charge such as electrons from being injected into the insulating film 110 and creating fixed charge in the insulating film 110. In this way, reliability in regard to characteristics change over time in the course of operation of the semiconductor can be improved.

The semiconductor device according to the present invention has the second drain offset region 105 formed within the first drain offset region 103 around the drain region 104 and having a smaller depth than the first drain offset region 103. The second drain offset region 105 has a higher impurity concentration than the first drain offset region 103; then, the first and second drain offset regions overall have a low resistance and the semiconductor device has a reduced on-resistance.

The second drain offset region 105 has a smaller depth than the first drain offset region 103, so that the second drain offset region 105 is included in the first drain offset region 103. Additionally, the second drain offset region 105 has a relatively high impurity concentration. With these two structures, a steep impurity concentration gradient is created near the border of the second drain offset region 105. When a high voltage is applied to the drain region 104, extension of a depletion layer particularly at the maximum curvature portion of the border of the second drain offset region 105 is suppressed, creating a high electric field.

The horizontal electric field distribution in the surface part of the first drain offset region 103 is overall smoothed as explained above and the average electric field value is low. Therefore, the semiconductor device according to the present invention can create the highest electric field near the maximum curvature portion of the border of the second drain offset region 105, not in the surface part of the first drain offset region 103 as in the prior art. Creating the highest electric field inside the first drain offset region 103 results in reducing charge injected into the insulating film 110, contributing to improvement of the semiconductor device in reliability. The breakdown voltage of the semiconductor device according to the present invention tends to be determined by the breakdown voltage inside the first drain offset region 103 where the highest electric field occurs. For this reason, the voltage resistance does not deteriorate and a given breakdown voltage can be maintained.

The second drain offset region 105 has a portion overlapping with the underside of the insulating film 110 as shown in FIG. 1 and has a relatively high impurity concentration. Therefore, the electric field is increased at the overlapping portion and there is a presumable risk of charge injection into the insulating film 110 or deterioration in the voltage resistance. However, in the present invention, the overlapping portion can be reduced in length along the underside of the insulating film 110. Then, the electric field at this portion can be suppressed so as not to exceed the electric field near the maximum curvature portion of the border of the second drain offset region 105.

More specifically, it is desirable that the overlapping portion of the second drain offset region 105 has a horizontal measurement of 1 μm or smaller, or the second drain offset region 105 is formed within 1 μm from the end of the drain region 104 that is closer to the source region 107. This is useful, for example, for a high voltage LDMOS transistor of a breakdown voltage class of 60 V and a semiconductor integrated circuit including it.

The semiconductor device according to the present invention has other advantages. For example, the second drain offset region 105 is shallower than the first drain offset region 103. Then, it substantially does not protrude from the bottom of the first drain offset region 103 and the bottom is almost flat. This serves to maintain the high breakdown voltage. Furthermore, the maximum curvature portion of the border of the body region 106 protrudes downward from the bottom of the first drain offset region 103. In other words, the body region 106 is deeper than the first drain offset region 103. The first PN junction mentioned above has a smaller curvature, so that the electric field concentration at this part is prevented and the breakdown voltage is increased.

### Embodiment 2

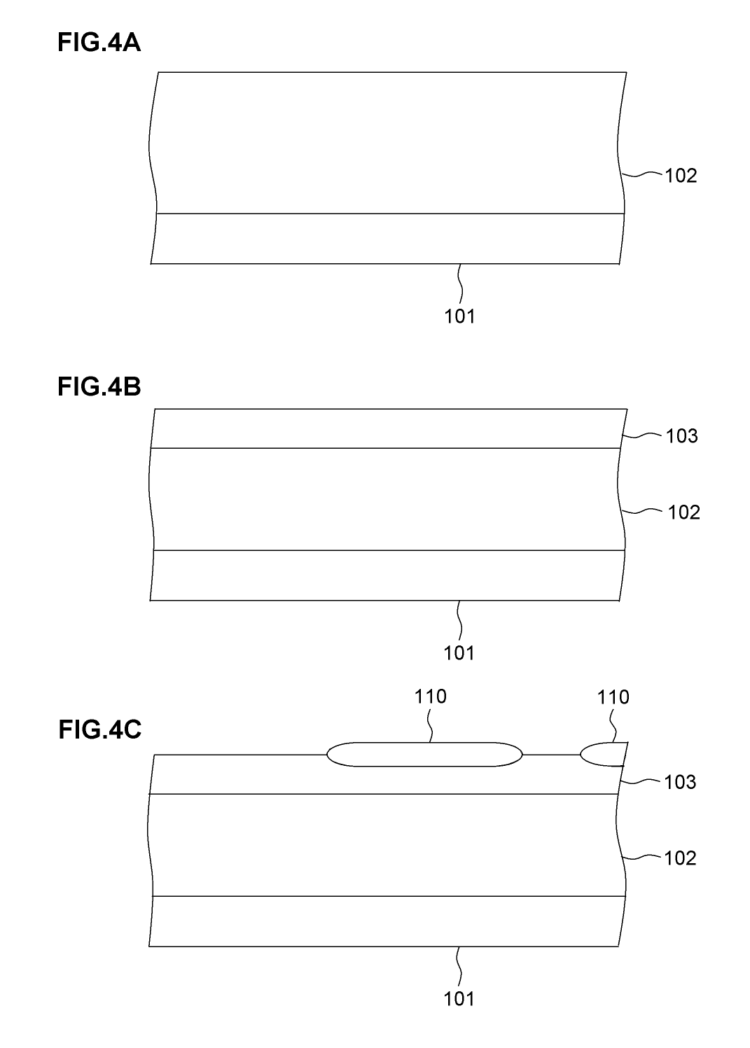

Embodiment 2 according to the present invention provides a method of producing the semiconductor device according to Embodiment 1. FIGS. 4 to 6 are cross-sectional views depicting the process of the semiconductor device production method according to Embodiment 2. In these figures, a part of a P channel LDMOS transistor region is shown as in FIG. 1. First, as shown in FIG. 4 (a), an N type semiconductor layer 102 is formed on a P type silicon substrate 101 to a thickness of 4 μm to 6 μm by an epitaxial technique. The semiconductor layer 102 can be formed by ion implantation of an N type impurity such as phosphorus into the silicon substrate 101, which is followed by high-temperature and long time thermal diffusion.

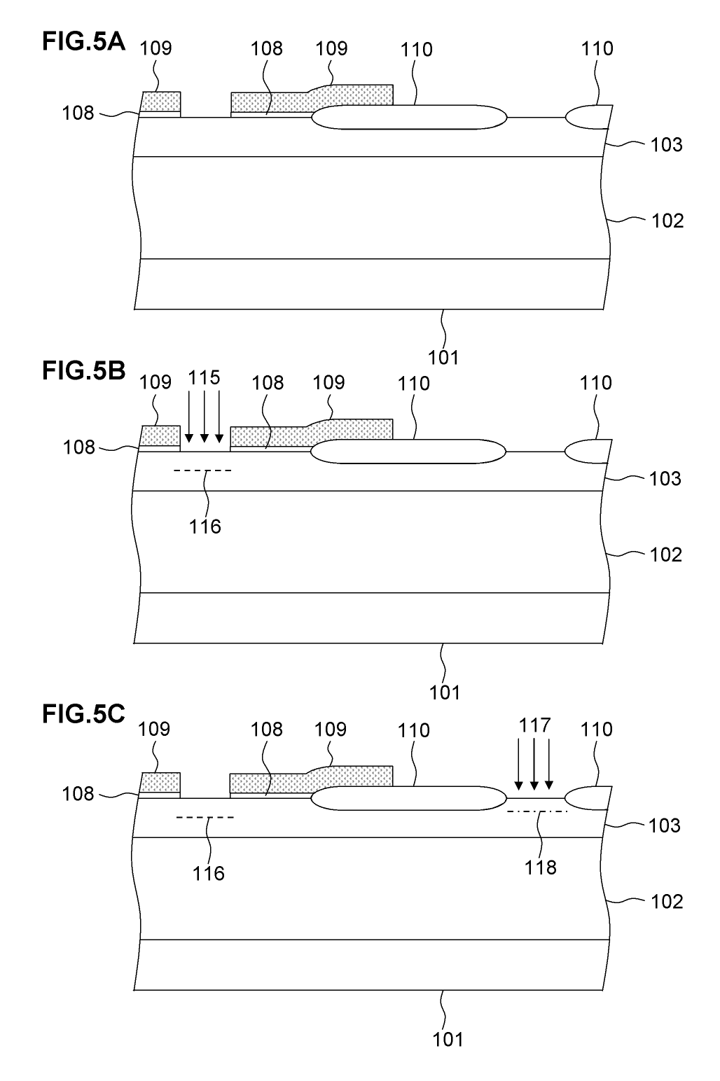

Then, as shown in FIG. 4 (b), boron is ion-implanted in a given region of the semiconductor layer 102 and thermal-diffused to form a first drain offset region 103 having a depth of smaller than 1 μm below the surface of the semiconductor layer 102. Then, as shown in FIG. 4 (c), an insulating film 110 consisting of a LOCOS oxide film is grown by a known selective oxidation technique in given regions on the surface of the semiconductor layer 102. Furthermore, as shown in FIG. 5 (a), the entire surface is exposed to thermal-oxidation to grow a gate insulating film 108 on the surface of the first drain offset region 103 which is exposed from the insulating film 110.

Then, a silicon film containing a high concentration N type impurity is grown on the entire surface by CVD. A not-shown resist film mask pattern is formed on the necessary part of the silicon film by lithography. Then, the silicon film is selectively dry-etched to form a gate electrode 109. Here, following the silicon film, the gate insulating film 110 is also selectively etched for removal. Then, the resist film used for the dry etching is removed. A not-shown resist pattern having an end on the gate electrode 109 and covering the unnecessary region is formed. Then, as shown in FIG. 5 (b), using the resist pattern and gate electrode 109 as a mask, phosphorus ions 115 are selectively implanted in the first drain offset region 103 to form an N type implanted layer 116. As described above, by using the gate electrode 109 as a part of the ion implantation mask in addition to the resist pattern, implantation along with self-alignment with respect to the gate electrode 109 is available. Therefore, a variation factor in the production process, namely relative position shift between the gate electrode 109 and N type implanted layer 116 is eliminated.

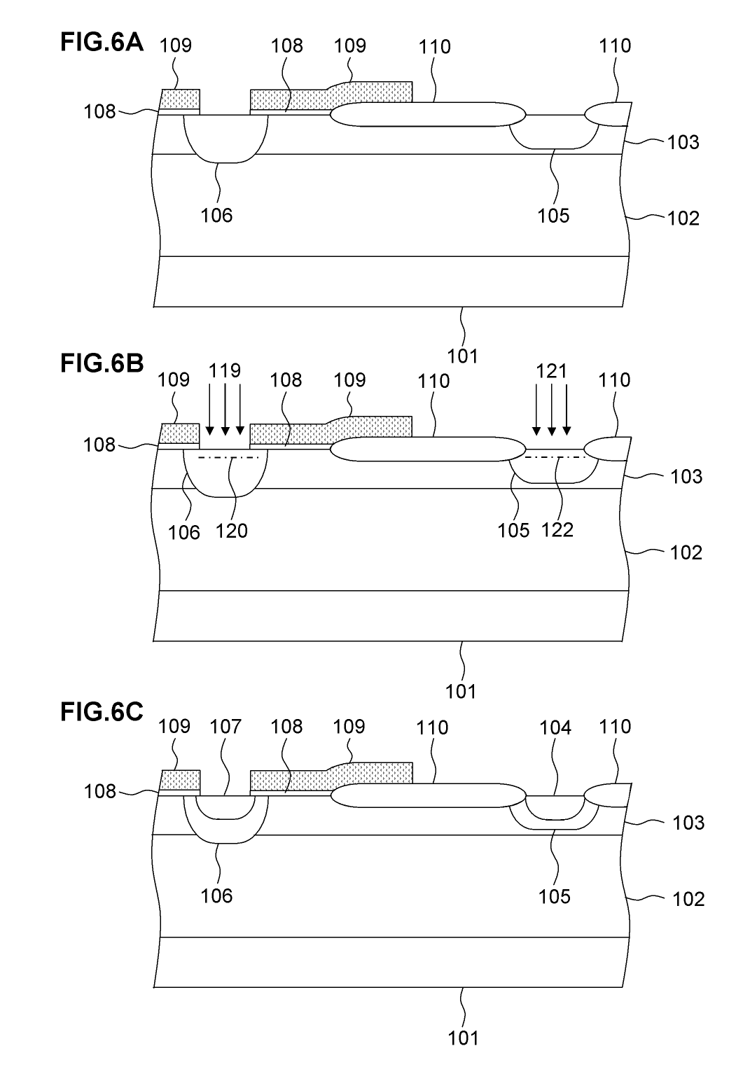

Then, as shown in FIG. 5 (c), after the removal of the resist pattern, a not-shown new resist pattern having an opening at a given position where the first drain offset region 103 is exposed between the insulating films 110 is formed. Boron ions 117 are ion-implanted using the new resist pattern as a mask to form a P type implanted layer 118. Then, although this is not shown in FIG. 6 (a), the silicon film constituting the gate electrode 109 is thermal-oxidized to form a thin silicon oxide film on the surface of the gate electrode 109 for ensuring the voltage resistance between the gate electrode 109 and other parts. Heat treatment accompanying the above thermal oxidation activates and diffuses the impurities in the N type implanted layer 116 and P type implanted layer 118 to form a body region 106 and a second drain offset region 105, respectively. The heat treatment conditions for the thermal oxidation include the temperature and time that make the body region 106 deeper than the first drain offset region 103 and make the second drain offset region 105 less deeper than the same.

Then, as shown in FIG. 6 (b), boron ions or boron fluoride ions 119 and 121 are ion-implanted in the body region 106 and second drain offset region 105 to a high concentration using the gate electrode 109 and insulating film 110 as a mask to form P type high concentration implanted layers 120 and 122. This ion implantation is conducted using a resist pattern covering a given region other than the region shown in FIG. 6 (b) and the body contact regions 112 shown in FIG. 2. Then, the resist pattern is removed. A new resist pattern having an opening at a position where the body contact regions 112 are to be formed is formed. Phosphorus ions or arsenic ions are ion-implanted to a high concentration using the new resist pattern as a mask.

Then, high temperature heat treatment is conducted to activate and diffuse the implanted impurity ions so as to form a source region 107, a drain region 104, and body contact regions 112. Although this is not shown in FIG. 6 (c), this heat treatment can be heat treatment that is conducted after an interlayer insulating film is formed on the entire surface including the gate electrode 109 and insulating film 110 to increase the density of the interlayer insulating film. After the interlayer insulating film is formed, contact holes 111 and 113 are formed therein above the drain region 104 and source region 107. Electrodes and wires made of an aluminum-based alloy are formed on the contact holes to complete the semiconductor device.

### Embodiment 3

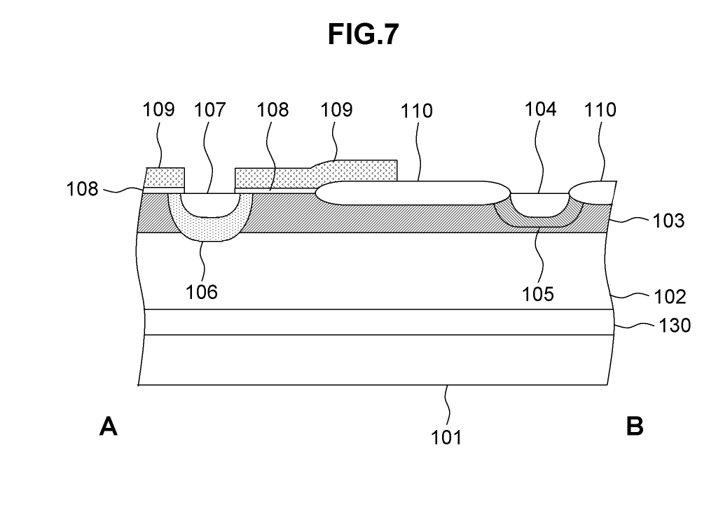

FIG. 7 is a cross-sectional view showing the structure of a semiconductor device according to Embodiment 3 of the present invention. The semiconductor device of this embodiment has the same planar layout pattern as the semiconductor device of Embodiment 1 (see FIG. 2). FIG. 7 shows a cross-section at the line A-B in FIG. 2. Since the semiconductor device shown in FIG. 7 has nearly the same structure as the semiconductor device of Embodiment 1, the same components are referred to by the same reference numbers and their explanation is omitted. Here, the difference will primarily be described. The same components as in the semiconductor device of Embodiment 1 are the same in shape, size, relative position, and impurity concentration as those in Embodiment 1.

The semiconductor device of this embodiment has an N type embedded diffusion layer 130 formed between the P type silicon substrate 101 and N type semiconductor layer 102 and having a significantly higher impurity concentration (for example, 1×10¹⁹ cm⁻³ or higher) than the N type semiconductor layer 102. This structure can be obtained as follows. An N type impurity ion such as arsenic and antimony is ion-implanted in the surface part of a silicon substrate 101 at least in a region where the semiconductor device is to be formed and subject to given heat treatment to form an embedded diffusion layer 130. Subsequently, an N type semiconductor layer 102 is formed by an epitaxial technique. The semiconductor device of this embodiment can be produced by the production method of Embodiment 2 except for the steps regarding formation of the N type embedded diffusion layer 130.

The embedded diffusion layer 130 having a high impurity concentration serves to reduce the resistance of the N type semiconductor layer 102 in part. Then, a parasitic bipolar transistor constituted by the P type silicon substrate 101, N type semiconductor layer 102, P type drain region 104 has a lower current gain, preventing a large current from flowing through the semiconductor device during the operation. For example, in the case of an IC driving a motor, power loss due to a leak current based on a regenerative current flowing backward from the motor to the IC when the motor is abruptly decelerated can be suppressed. For this reason, it is desirable that the embedded diffusion layer 130 has a peak impurity concentration of 1×10¹⁹ cm⁻³ or higher.

Furthermore, when a high voltage is applied to the drain region 104 in the structure wherein the embedded diffusion layer 130 is provided below the semiconductor layer 102, a depletion layer occurring in the semiconductor layer 102 does not easily extend into the embedded diffusion layer 130 while it easily extends into the first drain offset region 103. This effect allows the first drain offset region 103 directly below the insulating film 110 and gate electrode 109 to more easily be depleted; the crosswise electric field distribution in the surface part of the first drain offset region 103 is smoothed and alleviated. Then, the breakdown voltage at the PN junction between the body region 106 and first drain offset region 103 is more increased and, simultaneously, the semiconductor device is improved in reliability in regard to characteristics change over time as in Embodiment 1.

A depletion layer also easily extends upward from the semiconductor layer 102 into the region of the first drain offset region 103 where the second drain offset region 105 is located. However, the second drain offset region 105 has a high impurity concentration and suppresses extension of the depletion layer. Thus the electric field near the border of the second drain offset region 105 is increased and the breakdown voltage of the semiconductor device is highly possibly determined particularly at the maximum curvature portion of the border. As described above, because of the presence of the embedded diffusion layer 130, a depletion layer occurring in the semiconductor layer 102 does not easily extend into the embedded diffusion layer 130 and, by way of compensation, easily rushes and extends into the first drain offset region 103.

However, the first drain offset region 103 of the semiconductor device of this embodiment basically has a depth of 1 μm or smaller. As the first drain offset region 103 is shallower, the thickness of the semiconductor layer 102 or the distance between the bottom of the first drain offset drain 103 and the upper surface of the embedded diffusion layer 130 is increased. In this way, a larger space is assured in the semiconductor layer 102 for a depletion layer to extend in the vertical direction compared with the prior art structure. Then, the electric field intensity near the border of the second drain offset region 105 is alleviated. Downward extension of the depletion layer is suppressed at the boundary between the semiconductor layer 102 and embedded diffusion layer 130 because of a high impurity concentration of the embedded diffusion layer 130; the electric field intensity is increased. However, the semiconductor layer 102 is thick and the depletion layer extends more in the semiconductor layer 102; the electric field is alleviated and the breakdown voltage lowering can be prevented.

When the embedded diffusion layer 130 is formed, the breakdown voltage lowering can also be prevented by initially giving the N type semiconductor layer 102 a sufficiently large depth (thickness). However, the depth of the semiconductor layer 102 of an actual semiconductor integrated circuit is determined in consideration of not only the semiconductor device shown in FIG. 7 but also other MOS transistors integrated on the same silicon substrate. Therefore, free design change is difficult.

### Embodiment 4

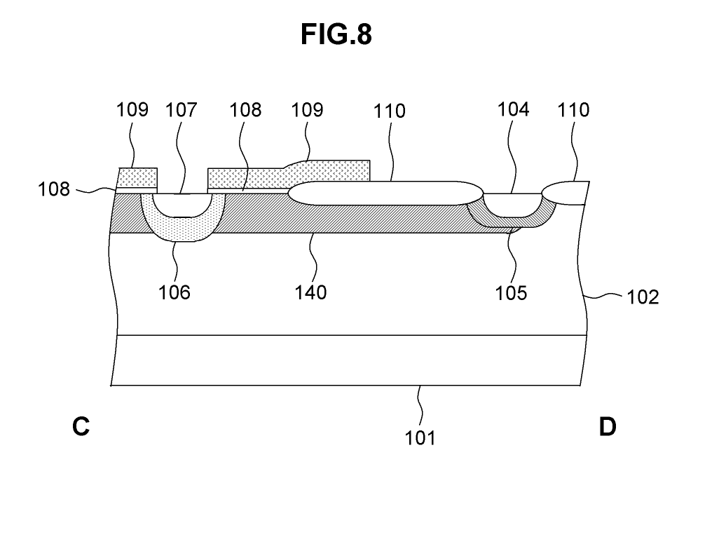

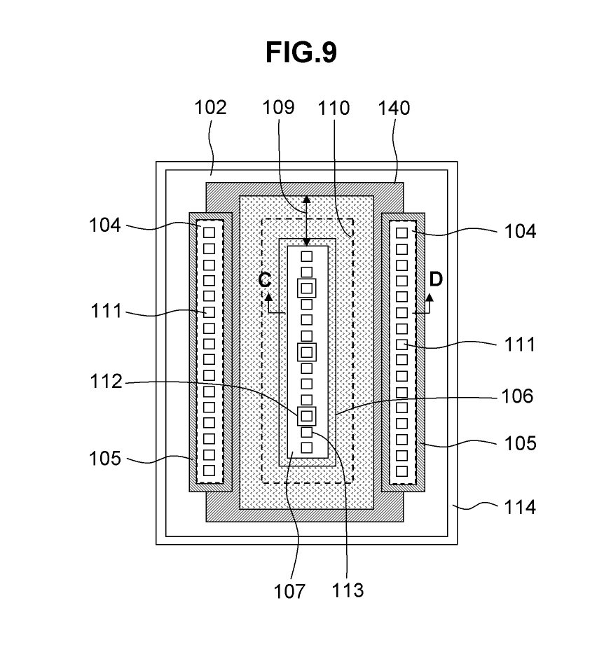

FIG. 8 is a cross-sectional view showing the structure of a semiconductor device according to Embodiment 4 of the present invention and FIG. 9 is a plane view showing the planar layout pattern thereof. FIG. 8 shows a cross-section along the line C-D in FIG. 9. Since the semiconductor device shown in FIGS. 8 and 9 has nearly the same structure as the semiconductor of Embodiment 1, the same components are referred to by the same reference numbers and their explanation is omitted. The difference will primarily be described. The components having the same reference numbers as in the semiconductor device of Embodiment 1 are the same in shape, size, relative position, and impurity concentration as those in Embodiment 1.

In the semiconductor device of this embodiment, as shown in FIGS. 8 and 9, of the maximum curvature portions of the boundary between the second drain offset region 105 and a first drain offset region 140, at least the one closer to the source region 107 is included in the first drain offset region 140 and a part of the second drain offset region 105 is horizontally exposed outside the first drain offset region 140. This structure is intended to diminish the first drain offset region 140 toward the source region 107 as shown in FIG. 9. In this way, the first drain offset region 140 has a reduced occupancy and the element isolation region 114 can be diminished to reduce the area of the semiconductor device.

As shown in FIG. 9, more specifically, of the boundary between the first drain offset region 140 and semiconductor layer 102 in a planar view, the border extending in the direction perpendicular to the direction from the source region 107 to the drain region 104 (of the ends of the first drain offset region 140, the end extending in the direction perpendicular to the direction from the source region 107 to the drain region 104) makes contact with the bottom of the second drain offset region 105. It is desirable that the border or end of the first drain offset region 140 overlaps with the second drain offset region 105 as described above.

The border of the second drain offset region 105 has two maximum curvature portions as shown in FIG. 8. It is the maximum curvature portion closer to the source region 107 where the electric field generated when a high voltage is applied to the drain region 104 concentrates and creates a high electric field to determine the breakdown voltage. One of the factors creating this high electric field is a depletion layer primarily extending toward the drain region 104 from the first PN junction as described in Embodiment 1. On the other hand, the second drain offset region 105 having a higher impurity concentration than the first offset region 140 and the semiconductor layer 102 directly form a PN junction at the other maximum curvature portion. However, the semiconductor layer 102 has a significantly lower impurity concentration than the first drain offset region 140 and body region 106; therefore, a relatively low electric field occurs at this portion.

In the above state, even if a part of the second drain offset region 105 is horizontally exposed outside the first drain offset region 140, almost no breakdown voltage lowering occurs and the same effect as the semiconductor devices of Embodiments 1 and 3 can be obtained. The semiconductor of this embodiment is different from the semiconductor device of Embodiment 1 only in the pattern geometry of the first drain offset region 140 and can be produced by the method of Embodiment 2.

### Embodiment 5

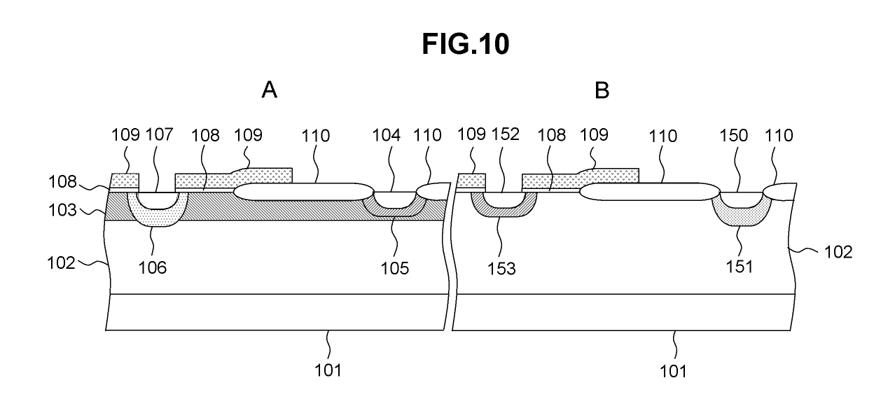

FIG. 10 is a cross-sectional view showing a semiconductor device according to Embodiment 5 of the present invention. This semiconductor device comprises a semiconductor device A (a semiconductor device according to Embodiment 1, more specifically a P channel LDMOS transistor) and a semiconductor device B (more specifically an N channel LDMOS transistor) on the same silicon substrate. The semiconductor device A is described in detail in Embodiment 1; the same components are referred to by the same reference numbers and their explanation is omitted. The semiconductor device B will primarily be described.

In the semiconductor device B, a low impurity concentration N type semiconductor layer 102 is formed on a P type silicon substrate 101. A P type body region 153 is formed in the surface part of the semiconductor layer 102 and an N type drain offset region 151 is formed at a given position on the semiconductor layer 102 with a distance from the P type body region 153. The N type drain offset region 151 has a higher impurity concentration than the semiconductor layer 102. A high impurity concentration N type source region 152 is formed in the body region 153. Furthermore, a not-shown high impurity concentration P type body contact region is also formed in the body region 153. The body contact region corresponds to the N type body contact region (112 in FIG. 2) of the semiconductor device A and is normally electrically connected to the body region 153. The body contact region is short-circuited to the source region 152 for use.

A high impurity concentration N type drain region 150 is formed in the N type drain offset region 151. Furthermore, an insulating film 110 consisting of an LOCOS oxide film, a gate insulating film 108 consisting of a silicon oxide film or the like, and a gate electrode 109 are formed on the surface of the semiconductor layer 102 in the same layout as in the semiconductor device A. With the above structure, the semiconductor layer 102 extending from the end of the N type drain offset region 151 to the PN junction region with the body region 153 via directly below the insulating film 110 and directly below the gate electrode 109 works as a low impurity concentration N type drain offset region corresponding to the first drain offset region 103 in the semiconductor device A. The semiconductor device B has the same planar layout pattern as shown in FIG. 2 except that the components have different conductivity types.

The semiconductor device A is constructed as follows for increasing the breakdown voltage and improving the reliability in regard to characteristics change over time in the course of operation. The P type first drain offset region 103 has a depth of 1 μm or smaller. The second drain offset region 105 is shallower than the first drain offset region 103 and has a relatively high P type impurity concentration optimized for reducing the on-resistance. In order for the semiconductor device of this embodiment to operate particularly at a ten plus several V to several tens V, the second drain offset region 105 can be formed under the same conditions as the body region 153 of the semiconductor device B as an N channel LDMOS transistor. Then, these regions can be formed in the same production step. The semiconductor device shown in FIG. 10 has the same effect as the semiconductor device of Embodiment 1. Furthermore, there is no need of forming the second drain offset region 105 and body region 153 in separate steps, reducing the number of steps and suppressing increase in production cost.

A method of producing the semiconductor device shown in FIG. 10 is outlined as follows. First, an N type semiconductor layer 102 is formed on a P type silicon substrate 101. Then, a P type first drain offset region 103 is formed in a region of the semiconductor layer 102 where the semiconductor A is to be formed. Then, an insulating film 110 consisting of an LOCOS oxide film is selectively grown on the surface of the first drain offset region 103 and a region of the semiconductor layer 102 where the semiconductor device B is to be formed. Subsequently, a gate insulating film 108 is grown on the exposed surface where the insulating film 110 is absent. Gate electrodes 109 of the semiconductor devices A and B are formed thereon.

Ion implantation for an N type body region 106 of the semiconductor device A is conducted on a given portion of the first drain offset region 103. Subsequently, concurrent ion implantation for a P type second drain offset region 105 of the semiconductor device A and for a P type body region 153 of the semiconductor device B is conducted under the same conditions. Furthermore, ion implantation for an N type drain offset region 151 of the semiconductor device B is conducted on a given portion of the semiconductor layer 102.

Then, the surface of the gate electrode 109 is oxidized to form a thin oxide film and independent heat treatment is conducted to form a body region 106, second drain offset region 105, body region 153, and N type drain offset region 151. In this process, the second drain offset region 105 and body region 153 have substantially the same depth below the original surface of the semiconductor layer 102 and the same impurity concentration (peak concentration). Furthermore, a P type impurity is ion-implanted concurrently into the body region 106 and second drain offset region 105 of the semiconductor device A and a not-shown body contact region of the semiconductor device B to a high concentration.

Then, an N type impurity is ion-implanted concurrently into the body region 153 and N type drain offset region 151 of the semiconductor device B and a not-shown body contact region of the semiconductor device A to a high concentration. Then, high temperature heat treatment is conducted to form a P type source region 107, P type drain region 104, N type source region 152, and N type drain region 150, and body contact regions of the semiconductor devices A and B.

The above-described semiconductor devices according to Embodiments 1 to 5 are explained on the basis of a structure having two, right and left, drain regions provided symmetrically about the source region as shown in FIGS. 2 and 9 by way of example. However, one half of such a layout, namely one source region and one source drain region can be provided in parallel to each other in the longitudinal direction. Furthermore, although the embodiments of the present invention consist of a unit semiconductor device, the present invention includes an array of multiple semiconductor devices having the same structure.

Furthermore, the semiconductor devices explained in the above embodiments consist of a P channel LDMOS transistor. At least the semiconductor layer 102 and impurity doped semiconductor regions formed in the semiconductor region 102 can have the conductivity types switched between the N type and P type. Furthermore, in Embodiment 3, the conductivity type of the embedded diffusion layer 130 can be switched. Furthermore, the conductivity type of the silicon substrate 101 can also be switched.

The semiconductor device according to the present invention is not confined to a LDMOS transistor given in the embodiments by way of example. The present invention is also useful for other semiconductor devices particularly high voltage semiconductor devices, having an impurity layer of which function corresponds to that of a drain offset region.

What is claimed is:

1. A semiconductor device, comprising:
a semiconductor layer having a first conductivity type;
a first impurity region formed in the surface part of said semiconductor layer and having a second conductivity type;
a body region adjacent to and in contact with said first impurity region and having the first conductivity type;
a second impurity region formed in said first impurity region with a distance from said body region, having the second conductivity type, and having a depth smaller than said first impurity region;
a source region formed in the surface part of said body region and having the second conductivity type;
a drain region formed in the surface part of said second impurity region and having the second conductivity type; and
a gate electrode formed from above the end of said source region that is closer to said drain region to a region above said first impurity region via a gate insulating film.

2. The semiconductor device according to claim 1, wherein said body region has a larger depth than said first impurity region and the maximum curvature portion of the border of said body region is at a lower level than the bottom of said first impurity region.

3. The semiconductor device according to claim 1, wherein said second impurity region has a higher impurity concentration than said first impurity region.

4. The semiconductor device according to claim 1, wherein an embedded layer having the first conductivity type and a higher impurity concentration than said semiconductor layer is formed below said semiconductor layer.

5. The semiconductor device according to claim 1, wherein of the maximum curvature portions of the border of said second impurity region, the portion closer to said source region is included in said first impurity region and a part of said second impurity region is horizontally exposed outside of said first impurity region.

6. The semiconductor device according to claim 1, wherein said first impurity region has a depth of 1 μm or smaller.

7. The semiconductor device according to claim 2, wherein said first impurity region has a depth of 1 μm or smaller.

8. The semiconductor device according to claim 3, wherein said first impurity region has a depth of 1 μm or smaller.

9. The semiconductor device according to claim 4, wherein said first impurity region has a depth of 1 μm or smaller.

10. The semiconductor device according to claim 5, wherein said first impurity region has a depth of 1 μm or smaller.

11. The semiconductor device according to claim 3, wherein said second impurity region is formed within 1 μm from the end of said drain region that is closer to said source region in the direction to said source region on the surface.

12. The semiconductor device according to claim 2, wherein said second impurity region has a higher impurity concentration than said first impurity region.

13. The semiconductor device according to claim 4, wherein said second impurity region has a higher impurity concentration than said first impurity region.

14. The semiconductor device according to claim 5, wherein said second impurity region has a higher impurity concentration than said first impurity region.

15. A semiconductor device, having:
a first semiconductor device comprising:
a semiconductor layer having a first conductivity type;
a first impurity region formed in the surface part of said semiconductor layer and having a second conductivity type;
a first body region adjacent to and in contact with said first impurity region and having the first conductivity type;
a second impurity region formed in said first impurity region with a distance from said first body region, having the second conductivity type, and having a depth smaller than said first impurity region;
a first source region formed in the surface part of said first body region and having the second conductivity type;
a first drain region formed in the surface part of said second impurity region and having the second conductivity type; and
a gate electrode formed from above the end of said first source region that is closer to said first drain region to a region above said first impurity region via a gate insulating film,
and a second semiconductor device comprising:
said semiconductor layer;
a second body region formed in the surface part of said semiconductor layer, having the same depth and impurity concentration as said second impurity region, and having the second conductivity type;
a third impurity region formed in the surface part of said semiconductor layer with a distance from said second body region and having the first conductivity type;
a second source region formed in the surface part of said second body region and having the first conductivity type;
a second drain region formed in the surface part of said third impurity region and having the first conductivity type; and
a gate electrode formed from above the end of said second source region that is closer to said second drain region to a region above said semiconductor layer via a gate insulating film.

16. A semiconductor device production method, including the steps of:
forming a first impurity region having a second conductivity type in the surface part of a semiconductor layer having a first conductivity type;
forming a gate insulating film on the surface of said first impurity region;
forming a gate electrode on said gate insulating film;
introducing an impurity having the first conductivity type in said first impurity region using said gate electrode as a mask to form a body region;
introducing an impurity having the second conductivity type in said first impurity region at a given position away from said body region to form a second impurity region having a depth smaller than said first impurity region;
introducing an impurity having the second conductivity type in said body region using said gate electrode as a mask to form a source region; and
introducing an impurity having the second conductivity type in said second impurity region to form a drain region.

17. The semiconductor device production method according to claim 16, wherein said first impurity region has a depth of 1 μm or smaller.

18. The semiconductor device production method according to claim 16, wherein further including a step of introducing an impurity having the first conductivity type in the semiconductor substrate to form an embedded layer having a higher impurity concentration than said semiconductor layer and a step of forming said semiconductor layer on said embedded layer.

19. A method of producing the semiconductor device according to claim 15, wherein said second impurity region and second body region are formed concurrently in the same step.

20. The semiconductor device production method according to claim 19, wherein said first impurity region has a depth of 1 μm or smaller.
